(19) United States
(12) Patent Application Publication
(10) Pub. No.: US 2024/0270964 A1
(43) Pub. Date: Aug. 15, 2024

(54) PHOTOTHERMAL CURING OF THERMOSET RESINS

(71) Applicant: The Penn State Research Foundation, University Park, PA (US)

(72) Inventors: Benjamin J. LEAR, University Park, PA (US); Robert J. FORTENBAUGH, University Park, PA (US); Kaitlin HAAS, Langhorne, PA (US)

(21) Appl. No.: 18/490,614

(22) Filed: Oct. 19, 2023

Related U.S. Application Data
(63) Continuation of application No. 16/610,249, filed on Nov. 1, 2019, now abandoned.
(60) Provisional application No. 62/502,034, filed on May 5, 2017.

(51) Int. Cl. C08L 83/04; B29C 64/124; B29K 83/00; B33Y 10/00; B33Y 70/00

(52) U.S. Cl. CPC C08L 83/04; B29C 64/124; B33Y 10/00; B33Y 70/00; B29K 2083/00; C08L 2203/30; C08L 2205/025

(57) ABSTRACT

Thermosetting formulations useful for forming bulk structures such as in additive manufacturing can include (a) a compound including reactive functional groups, (b) a curing agent having functional groups reactive with the reactive functional groups of the compound, and (c) a photothermally active material. Such formulations can be cured by applying actinic radiation to the formulation.

### CROSS-REFERENCE TO RELATED APPLICATION

This application is a continuation of U.S. patent application Ser. No. 16/610,249, filed on Nov. 1, 2019, which is a national stage application of international application PCT/US2018/031138, filed on May 4, 2018, which claims the benefit of U.S. Provisional Application No. 62/502,034, filed May 5, 2017, all of which are incorporated herein by reference in their entirety.

### STATEMENT REGARDING FEDERALLY SPONSORED RESEARCH

This invention was made with government support under Grant No. W911NF-16-1-0123 awarded by the U.S. Army/ARO. The Government has certain rights in the invention.

### TECHNICAL FIELD

The present disclosure relates to bulk photothermal curing of thermosetting resins, such as polysiloxane formulations, with photothermally active material such as nanometal particles which absorb actinic radiation and use of such formulation in additive manufacturing among other processes.

### BACKGROUND

Plasmonic heating via the photothermal effect of metal nanoparticles and its subsequent use to drive chemical reactions has the potential to revolutionize many aspects of traditional chemical synthesis. To date, photothermal heating has been demonstrated as an effective method to drive the decomposition of simple organic molecules and polymers, dissociation of H₂, photocatalysis and formation of chemical bonds. Many of these transformations prove difficult, however, because they require high bulk temperatures to accomplish.

Nanolithography by plasmonic heating of polydimethylsiloxane has also been disclosed. See Fedoruk et al. ACS Nano 2013:7(9):7648-7653. This reference discloses the synthesis of nanostructures but does not disclose bulk photothermal curing. Further, U.S. Patent Application Publication No 2016/0333220 discloses curable film forming compositions that can be use in coatings but does not disclose bulk photothermal curing such as additive manufacturing.

Hence, there is a continuing need for thermosetting formulations that can be used in bulk polymerization including additive manufacturing.

### SUMMARY OF THE DISCLOSURE

An advantage of the present invention is a thermosetting formulation useful for forming bulk structures such as in additive manufacturing.

These and other advantages are satisfied, at least in part, by a method of forming a three-dimensional object by depositing a thermosetting formulation onto a target and applying actinic radiation to the deposited formulation to cure the formulation to form a first layer of cured formulation; and repeating the deposition of thermosetting formulation with application of actinic radiation to the first layer to cure additional formulation to form additional cured layers on the first layer and form a three-dimensional object including the cured formulation. The thermosetting formulation can be comprised of: (a) a compound including reactive functional groups, (b) a curing agent having functional groups reactive with the reactive functional groups of the compound, and (c) a photothermally active material.

Another aspect of the present of the present disclosure includes a formulation comprising a homogenized mixture of (a) a polysiloxane having one or more vinyl groups, (b) a polysiloxane having one or more Si—H groups, and (c) a photothermally active material. In certain embodiments, the photothermally active material can be prepared in situ.

Additional advantages of the present invention will become readily apparent to those skilled in this art from the following detailed description, wherein only the preferred embodiment of the invention is shown and described, simply by way of illustration of the best mode contemplated of carrying out the invention. As will be realized, the invention is capable of other and different embodiments, and its several details are capable of modifications in various obvious respects, all without departing from the invention.

### BRIEF DESCRIPTION OF DRAWINGS

Reference is made to the attached drawings, wherein elements having the same reference numeral designations represent similar elements throughout and wherein:

FIGS. 1A and 1B are plots of infrared (IR) spectral data. FIG. 1A is a plot of such data to show the difference in the spectra of a polymer mixture upon mixing and after 24 hours of curing under ambient conditions, and FIG. 1B is a plot showing an intensity of Si—H stretch obtained during the 24-hour cure.

FIGS. 2A-2D show images and a histogram. FIG. 2A shows an STEM image of AuNP (42±4 nm) formed in situ within a thermosetting polydimethylsiloxane (PDMS) formulation in accordance with embodiments of the present disclosure, FIG. 2B shows an SEM image of gold nanoparticles (AuNPs) (100±18 nm) within photothermally cured PDMS, FIG. 2C shows a magnified section of AuNPs from FIG. 2B, and FIG. 2D shows histograms comparing relative AuNP sizes from uncured (a) and cured (b) PDMS.

FIGS. 3A-3B are plots. FIG. 3A is a plot of IR data showing a comparison of loss in intensity of Si—H stretch (2162 cm⁻¹) over time during PDMS curing under various conditions that were examined. Error bars are standard deviations over three measurements. FIG. 3B is a plot showing the relative rates of reaction under all conditions. The rates were obtained from linear fits of the data in FIG. 3A and reported with respect to pure PDMS. Error bars are the errors in the slope of the least squares linear regression shown in FIG. 3A.

FIG. 4 shows mass spectra for AuNP PDMS cured in the presence and absence of light with comparison of the relative number of counts and difference in counts between these conditions.

### DETAILED DESCRIPTION OF THE DISCLOSURE

The present disclosure relates to thermosetting formulations that can advantageously be used in additive manufacturing, e.g., three-dimensional printing. Thermoset polymers are a widely used class of materials for household products and packaging, protective mechanical coatings, and medical and chemical devices. Currently, thermoset polymers can either be thermally or optically cured. Optically cured thermosets are used for manufacturing. However, effective on-demand curing has yet to be realized for thermally cured analogs. In part, this realization is hampered by the difficulty in applying heating and cooling cycles to the pre-polymer mixtures on very short timescales.

While our previous studies on polyurethanes would lead us to expect that the photothermal effect would only enhance the curing rate (i.e., crosslinking rate), the inhibition of the reaction in the absence of light was a surprise. This is a desirable property for bulk polymerization and for large-scale commercial curing of polymers since it allows for longer working times after mixing of pre-polymers. By combining the added benefit of increased pot-life with the sought-after ability of on-demand, bulk curing of polymers, our approach offers a significant advantage to 3-D printing of thermosetting material.

We have found that plasmonic heating by photothermally active materials such as metal nanoparticles can deliver heating/cooling cycles with nanosecond lifetimes sufficiently short to provide effective on-demand curing of thermally cured thermosets. Hence, an aspect of the present disclosure includes processes of forming a three-dimensional object by additive manufacturing. As understood in the art, additive manufacturing, also referred to herein as 3D printing, involves a process of joining materials to make three-dimensional objects, usually layer upon layer, as opposed to subtractive manufacturing methodologies. The fabrication of such objects can be carried out through the deposition of material using a print head, nozzle, or another printer technology.

For example, such process can include depositing a thermosetting formulation onto a target and applying actinic radiation to the deposited formulation to cure the formulation to form a first layer of cured formulation. The steps are repeated by depositing additional thermosetting formulation with application of actinic radiation to the first layer to cure additional formulation to form additional cured layers on the first layer.

Thermosetting formulations useful for the present disclosure comprise: (a) a compound including reactive functional groups (such as vinyl groups, epoxy groups, alcohols, ethanoyl groups, acid chlorides, dienophiles, etc.); (b) a curing agent having functional groups reactive with the reactive functional groups of the compound (such groups include Si—H groups, SiOH, SiCl, dienes etc.); and (c) a photothermally active material such as particles made from metals (gold, silver, copper, ruthenium, palladium, platinum, aluminum, etc.), semiconductors (Si, Ge, CdS, CdSe, TiO₂, CuSSe, etc.), and insulators (SiO₂, diamonds, styrene, etc.), carbon based additives (carbon nanotubes, carbon black, carbon fiber, graphite, graphene, etc.) or molecular absorbers (Sudan IV, chlorophyll, Ru(bipy)₃, etc). This formation might also contain catalysts (Pt) or no catalysts. The formulation can also include a thermal initiator, such as an organic peroxide.

Suitable compounds including reactive functional groups for use in the formulation of the present disclosure include, for example, polysiloxanes having more than one vinyl groups, epoxy groups, alcohols, ethanoyl groups, acid chlorides, dienophiles, etc., as well as alkynes, ketones, aldehydes and mixtures of any of the foregoing.

Suitable curing agents having functional groups reactive with the reactive functional groups of the compound include, for example, polysiloxanes having more than one Si—H groups.

Suitable photothermally active materials that can be used in the formulations of the present disclosure include, for example, particles made from metals, semiconductors, insulators, carbon based additives, molecular absorbers, etc.

Photothermally active materials useful for the thermosetting formulations of the present disclosure include those that generate heat upon exposure to actinic radiation. Preferably such photoactive materials are those with strong light absorption properties coupled with weak light emission properties, which gives rise to a strong photothermal effect. Examples of photothermally active materials include silver, gold, aluminum, copper, titanium, chromium, magnetite, Si, Ge, Sn, GaAs, CdSe, AlGaAs, Fe₄[Fe(CN)₆]₃, Cu-phthalocyanine, HgS, a metal oxide, carbon, an organic dye, polythiophene, polyacetylene, and/or polyaniline. Advantageously, the photothermally active material included with thermosetting formulations of the present disclosure are sized as nanoparticles such as metal nanoparticles, e.g., gold nanoparticles (AuNPs), silver nanoparticles, platinum nanoparticles or other nanoparticles of transition metals or alloys thereof.

A particularly useful thermosetting formulation includes one or more polysiloxanes. Such materials, e.g., a polydimethylsiloxane (PDMS), are widely employed in medical, engineering, and scientific fields due to low cost, high flexibility, ease of molding, non-toxic nature, and chemical inertness. For these applications, PDMS devices are often made from casts and molds. Hence, another aspect of the present disclosure includes a process of photothermally curing a thermosetting formulation including one or more polysiloxane. Such a formulation can be cure to form bulk structures (e.g., structures having a volume of at least 1 mm³ and preferably greater than 1 cm³) or large area films (e.g. at least as large as 1 mm², e.g., greater than 1 cm²). Such bulk structures can be formed by use of molds. Such polysiloxane formulations can also be used in additive manufacturing.

In another aspect of the present disclosure is photothermally curing a homogenized polysiloxane formulation by applying actinic radiation to such a formulation. Such a formulation can include: (a) a polysiloxane having one or more reactive functional groups such as vinyl groups, (b) a polysiloxane having one or more Si—H groups, and (c) a photothermally active material to cure the polysiloxane formulation. In an embodiment, the photothermally active material can be metal nanoparticles, such as gold nanoparticles (AuNPs), silver nanoparticles, platinum nanoparticles or other nanoparticles of transition metals or alloys thereof. The photothermally active material promotes crosslinking of the polysiloxanes.

Appropriate mixtures of the polysiloxane having one or more vinyl groups can also be used in the thermosetting formulation. The amount of such polysiloxanes in the formulation generally ranges from 5 to 75 percent by weight based on the total weight of the polysiloxane in the formulation. For example, the minimum amount of polysiloxane having one or more vinyl groups can be at least 5 percent by weight, often at least 10 percent by weight and more often, at least 15 percent by weight. A high end amount of the polysiloxane having one or more vinyl groups can be 75 percent by weight, more often 60 percent by weight, or 50 percent by weight. Ranges of can include, for example, 5 to 50 percent by weight, 5 to 60 percent by weight, 10 to 50 percent by weight, 10 to 60 percent by weight, 10 to 75 percent by weight, 15 to 50 percent by weight, 15 to 60 percent by weight, and 15 to 75 percent by weight.

The polysiloxane having one or more vinyl groups and the polysiloxane having one or more Si—H groups can include various organo groups, R, such an alkyl, e.g., methyl, ethyl, propyl, hexyl, cyclohexyl, aromatic, e.g., phenyl, pyridyl, etc. and the R groups can also be substituted with one or more or of a halogen, alcohol, thiol, selanol, amines, epoxide, isocyanate, carboxylic acid, aldehyde, ketone or form one or more of alkyl halides, ethers, esters, alkyl pendant groups, carboxylates, acrylates, isocyanates, ether, ester, thioether, saturated and unsaturated bonds, etc. Such a polysiloxane can be a linear polydimethylsiloxane that has a methyl group attached to most of the silicon atoms in the polymer. Additionally, the polysiloxanes having reactive groups can be a copolymer, a block copolymer or mixed-substituent polymer wherein the organo groups, R, as defined hereinabove, are not all the same.

When a thermosetting formulation of the present disclosure is exposed to actinic radiation, sufficient heat is generated by the photothermally active material to effect cure of the formulation. The heat generated by the photothermally active material enables the formation of a bond between reactive functional groups. For example, gold, silver and aluminum exhibit surface plasmon resonance when irradiated with light in a known range of wavelengths and intensities, causing a transient and localized (on a molecular scale) generation of heat that promotes chemical reaction between the functional groups on the other components of the formulation. In materials demonstrating surface plasmon resonance, the origin of photothermal heat is absorption of light by the surface plasmon resonance (SPR) of the metal particles, which excites a collective oscillation of electrons that quickly (femtoseconds) dephase, transferring energy as heat. The system can reach peak temperature on the picosecond timescale, and then transfers thermal energy away from the particles, elevating the temperature of the local molecular environment, but leaving the bulk temperature of the composition largely unperturbed. It is believed that the rapid cooling of the particles provides a mechanism for retaining species transiently generated (i.e., the crosslinked coating) at high temperatures. In other words, there is no time for the reaction to reverse itself because the heat is dissipated.

For example, it has been found that that photothermal heat can be harnessed to drive large scale chemical reactions by simultaneously generating many individual nano-reactions. For example, the curing rate of polydimethylsiloxane (PDMS) may be increased by a factor of 4.9×10⁹. Photothermal curing may occur via crosslinking reactions between vinyl and Si—H groups of the pre-polymer, and the course of the reaction was followed by monitoring the disappearance of infrared bands associated with these functional groups. Using mass spectroscopy, the major polymer m/z peaks may be verified as identical for both traditionally and photothermally cured polymers, indicating that the photothermal effect of AuNPs is an effective way in which to supply on-demand curing of PDMS.

A photothermally active material of any average particle size can be used according to the present invention, provided it generates sufficient heat for curing to take place when the formulation is exposed to actinic radiation. For example, the photothermally active material may be micron sized, such as 0.5 to 50 microns or 1 to 15 microns, with size based on average particle size. Alternatively, the photothermally active material may be nano sized, such as 10 to 499 nanometers, or 10 to 100 nanometers, with size based on average particle size. It will be appreciated that these particle sizes refer to the particle size of the photothermally active material at the time of incorporation into the formulation. Various coating preparation methods may result in the particles agglomerating, which could increase average particle size, or shearing or other action that can reduce or increase average particle size. Thus the photothermally active material (c) may be present in the form of particles such as microparticles and/or nanoparticles such as nanowires, nanorods, nanoplatlets, nanospheres and irregularly shaped particles of appropriate size.

Often the particles of photothermally active material have an average primary particle size of no more than 500 nanometers, such as no more than 50 nanometers, or no more than 2 nanometers, as determined by visually examining a micrograph of a transmission electron microscopy (“TEM”) image, measuring the diameter of the particles in the image, and calculating the average primary particle size of the measured particles based on magnification of the TEM image. One of ordinary skill in the art will understand how to prepare such a TEM image and determine the primary particle size based on the magnification. The primary particle size of a particle refers to the smallest diameter sphere that will completely enclose the particle. As used herein, the term “primary particle size” refers to the size of an individual particle as opposed to an agglomeration of two or more individual particles.

The amount of photothermally active material used in the formulation can vary. For example, the formulation can comprise 0.001 to 10 percent by weight photothermally active material, with minimums, for example, of 0.001 percent by weight, or 0.01 percent by weight, or 0.02 percent by weight, and maximums of 10 percent by weight, or 2 percent by weight. Exemplary ranges include 0.01 to 2 percent by weight, 0.02 to 1.0 percent by weight, 0.05 to 0.5 percent by weight and 0.05 to 0.1 percent by weight, with percent by weight based on the total weight of the polysiloxane.

Many photothermal transformations prove difficult because they require high bulk temperatures to accomplish; however, due to the localized nature of the photothermal effect, it is possible to drive these transformations near the particle surface while maintaining the bulk of the sample at room-temperature.

The photothermal effect drives bond formation in thermally cured thermoset polymers, as shown in the following Reaction Scheme 1:

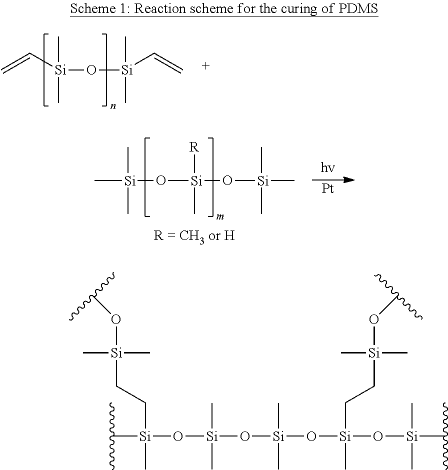

Thermosetting formulations of the present disclosure can be irradiated with pulsed actinic radiation at a wavelength, duration, and intensity sufficient to at least partially cure the formulation. In the photothermal heating, reactive functional groups on the components of the polysiloxane are crosslinked. Actinic radiation which can be used to cure coating compositions of the present invention generally has wavelengths of electromagnetic radiation ranging from 150 to 2,000 nanometers (nm), can range from 180 to 1,000 nm, and also can range from 300 to 1000 nm. Examples of suitable ultraviolet light sources include mercury arcs, carbon arcs, low, medium or high pressure mercury lamps, swirl-flow plasma arcs and ultraviolet light emitting diodes. Commonly used ultraviolet light-emitting lamps are medium pressure mercury vapor lamps having outputs ranging from 200 to 600 watts per inch (79 to 237 watts per centimeter) across the length of the lamp tube. Generally, a 1 mil (25 micrometers) thick wet film of a coating composition according to the present invention can be cured through its thickness to a tack-free state upon exposure to actinic radiation of wavelength 300 to 1000 nm. The typical duration of an actinic radiation pulse is from femtoseconds to microseconds, such as 1 femtosecond to 1 microsecond and the total exposure time to the pulsed radiation may range from microseconds to days, such as 1 microsecond to 48 hours. An intensity of 1 to 108 Watts per square centimeter of the wet film is typical. Particular exposure conditions are dependent upon the identity of the photothermally active material; i.e., the known light wavelength and intensity for maximum heat emission for a given photothermally active material.

Each of the characteristics and examples described above, and combinations thereof, are contemplated by the present disclosure.

### Examples

The following examples are intended to further illustrate certain preferred embodiments of the invention and are not limiting in nature. Those skilled in the art will recognize, or be able to ascertain, using no more than routine experimentation, numerous equivalents to the specific substances and procedures described herein.

In this example, the PDMS polymer system employed was Sylgard 184 (DOW Corning, Midland, MI), a two component system in which the elastomer contains vinyl-terminated siloxane oligomers, while the curing agent possesses Si—H moieties along a siloxane backbone.

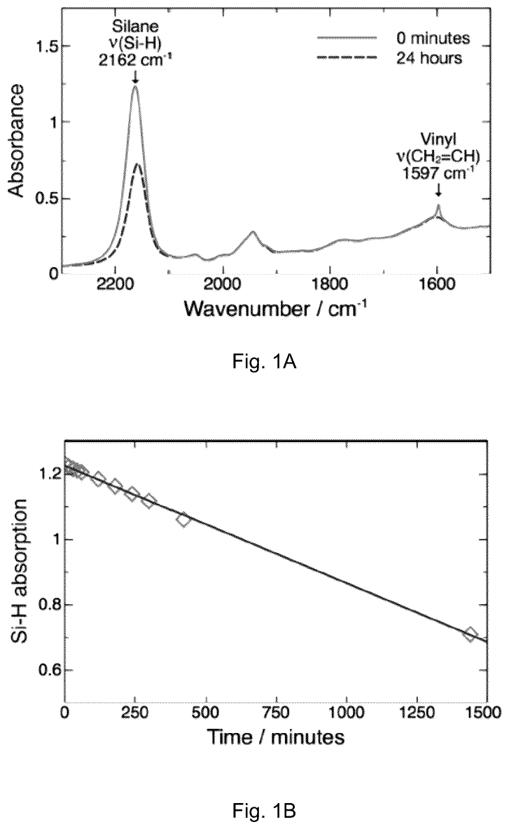

Crosslinking occurs between the vinyl group and Si—H bond. Upon curing, the characteristic infrared (IR) bands for both the vinyl (1597 cm-1) and Si—H stretch (2162 cm-1) groups reduce in intensity. FIG. 1A shows the difference in the spectra of the polymer mixture upon mixing and after 24 hours of curing under ambient conditions. Though both the Si—H and vinyl stretches disappear over the course of the reaction, the change in the Si—H intensity is far greater, and so this stretch functions as a more sensitive indicator for the course of the reaction. Indeed, the loss of intensity for the Si—H band is linear up to at least 24 hours, where the loss in intensity is 70% (FIG. 1B). This is a result that greatly simplifies the analysis of the impact of AuNPs and photothermal heating on the curing rate. In particular, the relative rates of Si—H loss under photothermal and non-photothermal conditions can be compared to determine the rate of curing relative to a 24 hour cure under ambient conditions.

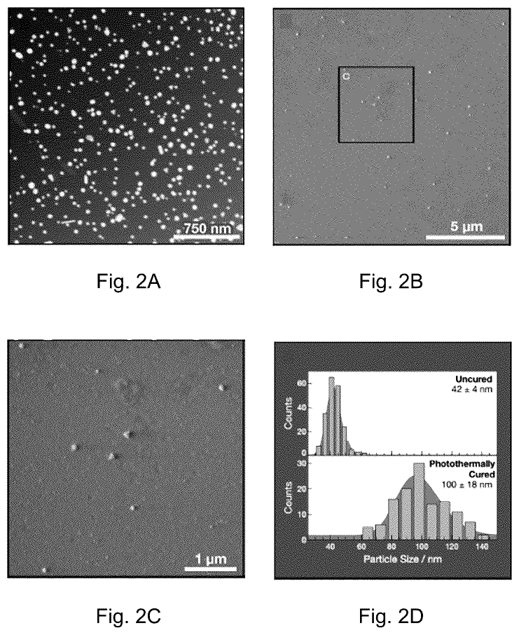

For this study, AuNP photothermal agents were prepared in situ by mixing an aqueous AuHCl₄ salt solution with the elastomer component of the PDMS pre-polymer (0.15% w/v). This provided a homogenized mixture of the Au salt in the elastomer. The Au salt is reduced by the elastomer, most likely via a small number of Si—H sites present. The reduced Au atoms form a mixture of AuNPs that are heterogeneous in both size (42±4 nm mean diameter) and shape (mostly spherical, with triangular prisms, hexagonal prisms, and rods present), as determined by scanning transmission electron microscopy (STEM) analysis (FIG. 2A,D). Given the weight percent of gold salt used and the size of the particles produced, the concentration of AuNPs in the resulting suspension can be estimated to be on the order of 10 nM, which is in agreement with analysis of the UV-vis spectra of these suspensions. The colloidal suspensions of these particles may be stable for at least one-year under ambient conditions. From a practical standpoint, this means that colloidal suspensions with photothermal agents can be prepared well before their final use.

However, in the experiments reported below, all colloidal suspension were prepared and used within six months. No difference in AuNP performance was observed as a function of age.

With elastomer/AuNP suspensions prepared, the ability of the photothermal effect to enhance the PDMS curing rate was examined. For this, a pre-polymer was prepared by mixing together the elastomer/AuNP suspension and curing component.

The pre-polymer was then cured within a liquid IR cell under either ambient conditions or by irradiation with 532 nm laser light (Quanta Ray 130 Nd:YAG). The laser generated 8 ns pulses at a 10 Hz repetition rate and was operated at fluencies of 0.80, 2.00, or 4.00 MW/cm². All fluencies induced changes in the AuNPs size and shapes with the AuNPs growing to a mean diameter of 100 18 nm, accompanied by a significant increase in the relative population of spherical particles (FIG. 2B-D).

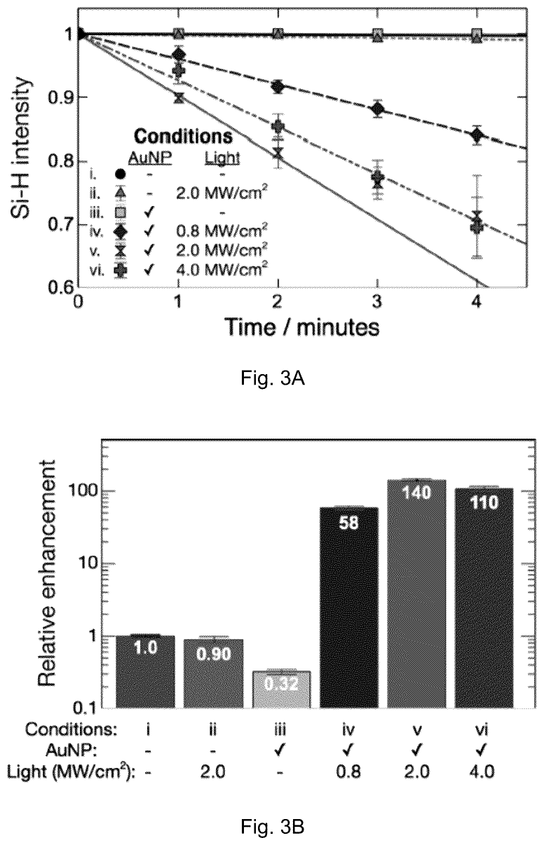

The course of the crosslinking reaction was again followed using IR spectra collected at 0, 1, 2, 3, and 4 minutes. The course of the crosslinking was determined from the percent decrease of the vinyl and Si—H bands, relative to the 24 hour ambient cure. This approach is validated by the data shown in FIG. 1B. Plotting this data versus time and performing a linear regression (FIG. 3A) yielded relative rates of the reaction under all conditions examined (FIG. 3B).

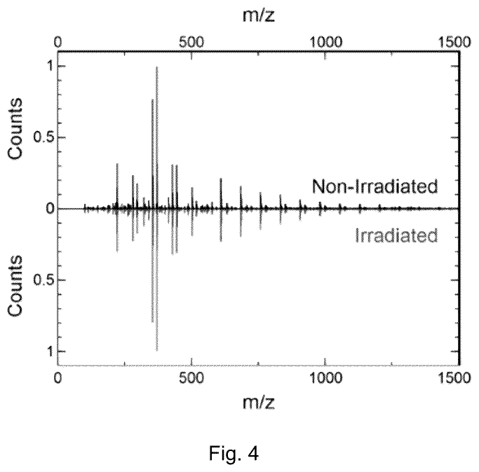

Here, it seems important to note that, though the loss of intensity in the vinyl and Si—H stretches is an excellent indicator for the extent of PDMS curing, it is not a direct probe for the formation of crosslinked sites, nor was a convenient IR handle for the formation of crosslinking identified. In order to verify the formation of a cross-linked product, electrospray ionization time-of-flight mass spectrometry on PDMS cured under all conditions was performed, as shown in FIGS. 3A-3B. Examples of the mass spectra obtained are shown in FIG. 4. Here, it is shown that PDMS cured photothermally (Condition v) produce the same m/z peaks, with nearly the same relative intensity, as those from PDMS films cured ambiently (Condition i) for twenty-four hours. This result indicates that the extent of crosslinking is similar in these two films, or that photothermal heating does not significantly affect the end product of curing.

There are at least three comments regarding the data presented in FIGS. 3A-3B. First, when AuNPs are synthesized in PDMS, the resulting composite cures at a rate roughly ⅓ of that for the pure PDMS system. The reason for this decrease in rate is not yet clear, though it is noted that removal of the AuNPs by centrifugation does not return the rate to that of pure PDMS. Thus, it seems that production of the AuNPs alters the PDMS pre-polymers in a way that decreases the rate of curing. This may be a result of loss of Si—H moieties through the proposed reduction of HAuCl₄, though it is noted that no significant changes were detected in the Si—H IR stretch during synthesis of the AuNPs. It is also possible that the by-products of AuNP synthesis inhibit the reaction. More work will be needed to isolate the cause of the slower curing.

The second result worth comment is that the photothermal effect significantly enhances the curing rate of PDMS relative to pure PDMS. It follows that the photothermal effect curing rate is even greater compared to the unirradiated AuNP-PDMS composite.

At a maximum, a roughly 440-fold increase to the rate of curing was observed in real-time for the 2.00 MW/cm² exposure. This result bring us to the final comment—the enhancement factor is a function of fluency but has a maximum. Increasing the laser fluency by a factor of 2.5 (from 0.80 to 2.00 MW/cm²) resulted in a 2.4 fold increase in cure rate. However, a further doubling of the fluency resulted in a slight decrease in the enhancement factor. The origin of this decrease is not currently known, though it is possible that extreme fluencies damage the polymer, inhibiting crosslinking. The fact that, in the absence of AuNPs, the use of light also slows down the reaction (Condition ii) supports this hypothesis.

Taking a closer look at the real-time rate enhancements, as the Arrhenius equation implies that a doubling of rate typically requires an increase in temperature of approximately 10 K, then a 440-fold increase in rate implies a change in temperature on the order of almost 90 degrees. However, the nanoparticles are only hot for roughly the duration of the laser pulse. Accounting for such short heating times, this implies an enhancement of the instantaneous rate on the order of 4.9×10⁹. This is an extraordinary rate enhancement which is roughly four times greater than what has been found for polyurethane and implies, according to the Arrhenius equation, a local temperature increase on the order of 320 K. However, the greatest bulk-scale temperature change measured was 12.5 K.

In addition to the short timescale of heating, the high temperatures supplied by the photothermal effect of AuNPs extends only nanometers from the surface. Given an estimation of the concentration of AuNPs (of 10 nM, it may be calculated that each pulse appreciably heats on the order of 0.01% of the total pre-polymer volume.

Over 4 minutes, the samples are exposed to 24,000 pulses, meaning that roughly 24% of the total sample volume is heated over this time frame. This is remarkably close to the total percentage cure shown in FIG. 3A for the irradiated samples and suggest that there is near 100% efficient crosslinking near the hot nanoparticles during each laser pulse. This is particularly surprising given that the reaction is exothermic since extreme temperatures should bias the transformation towards the reactants. This is a similar result to that seen for the urethane system and implies that photothermal heating cannot be treated using equilibrium considerations. At the same time, the ability to cure several different polymer systems demonstrates that photothermal heating does retain the generality of efficacy which has been the primary advantage of conventional heating.

Only the preferred embodiment of the present invention and examples of its versatility are shown and described in the present disclosure. It is to be understood that the present invention is capable of use in various other combinations and environments and is capable of changes or modifications within the scope of the inventive concept as expressed herein. Thus, for example, those skilled in the art will recognize, or be able to ascertain, using no more than routine experimentation, numerous equivalents to the specific substances, procedures and arrangements described herein. Such equivalents are considered to be within the scope of this invention, and are covered by the following claims.

What is claimed is:

1. A method of forming a three-dimensional object, the method comprising:
depositing a thermosetting formulation onto a target and applying actinic radiation to the deposited thermosetting formulation to cure the thermosetting formulation to form a first layer of a cured formulation; and
repeating the deposition of the thermosetting formulation with the application of the actinic radiation to the first layer to cure an additional formulation on the first layer to form a three-dimensional object including the cured thermosetting formulation;
wherein the thermosetting formulation comprises: (a) a compound including reactive functional groups, (b) a curing agent having functional groups reactive with the reactive functional groups of the compound, and (c) a photothermally active material, wherein the photothermally active material is 0.001-0.02 percent by weight of the thermosetting formulation and wherein the photothermally active material is not an organic dye.

2. The method of claim 1, wherein the thermosetting formulation comprises (a) a polysiloxane having one or more vinyl groups as the compound including reactive functional groups, (b) a polysiloxane having one or more Si—H groups as the curing agent, and (c) nanoparticles of a metal as the photothermally active material.

3. The method of claim 1, wherein the photothermally active material comprises silver, gold, aluminum, copper, titanium, chromium, magnetite, Si, Ge, Sn, GaAs, CdSe, AlGaAs, Fe₄[Fe(CN)₆]₃, Cu-phthalocyanine, HgS, a metal oxide, carbon, polythiophene, polyacetylene, and/or polyaniline.

4. The method of claim 2, wherein the thermosetting formulation comprises (a) a polydimethylsiloxane having one or more vinyl groups as the compound including reactive functional groups, (b) a polydimethylsiloxane having one or more Si—H groups as the curing agent.

5. A method of photothermally curing a polysiloxane formulation, the method comprising:
applying actinic radiation to a formulation including: (a) a polysiloxane having one or more vinyl groups, (b) a polysiloxane having one or more Si—H groups, and (c) a photothermally active material to cure the polysiloxane formulation.

6. The method of claim 5, wherein an intensity of the actinic radiation is from 1 to 10⁸ W/cm².

7. The method of claim 5, wherein the actinic radiation is applied to the formulation by pulsing actinic radiation.

8. The method of claim 5, wherein the duration of an actinic radiation pulse is from 1 femtosecond to 1 microsecond.

9. The method of claim 8, wherein the wavelength of actinic radiation is from 300 to 1000 nm.

10. The method of claim 1, wherein the actinic radiation is applied at an intensity at a range of 1 to 10⁸ W/cm².

11. A formulation comprising a homogenized mixture of (a) a polysiloxane having one or more vinyl groups, (b) a polysiloxane having one or more Si—H groups, and (c) a photothermally active material.

12. The formulation of claim 11, wherein the photothermally active material is prepared in situ.

13. The formulation of claim 12, wherein the photothermally active material is prepared in situ by mixing the polysiloxane having one or more Si—H groups and a precursor of the photothermally active material, wherein the polysiloxane having one or more Si—H groups reduces the precursor to generate the photothermally active material.
